(19) United States
(12) Patent Application Publication
(10) Pub. No.: US 2008/0257715 A1
(43) Pub. Date: Oct. 23, 2008

(54) Method of Deposition with Reduction of Contaminants in An Ion Assist Beam and Associated Apparatus

(76) Inventors: Peter Hoghoj, Saint Martin Le Vinoux (FR); Paraskevi Ntova, Fontaine (FR); Claude Montcalm, Gatineau (CA); Sergio Rodrigues, Voreppe (FR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/664,343

(22) PCT Filed: Oct. 13, 2004
(86) PCT No.: PCT/IB2004/003574

§ 371 Date: Mar. 3, 2008

(51) Int. Cl. C23C 14/34

(52) U.S. Cl. 204/192.11; 204/298.02

(57) ABSTRACT

The invention relates to a dual Ion Beam Sputtering method for depositing onto a substrate (S) material generated by the sputtering of a target (121-123) by a sputtering ion beam (110), said method comprising the operation of an assistance ion beam (130) directed onto said substrate in order to assist the deposition of material, said method being characterized in that during the operation of said assistance beam said sputtering beam is also operated in association with said assistance beam, and during said operation of the sputtering beam in association with the assistance beam the sputtering beam crosses a desired part of the assistance beam in order to transport contaminants associated to said desired part of the assistance beam away from said substrate.

The present invention concerns a method of material deposition on a substrate, and an associated apparatus.

More precisely, the deposition method concerned by the invention is of the DIBS type.

DIBS is the acronym of Dual Ion Beam Sputtering. It refers to a deposition method where two distinct ion beams are used in a chamber containing a substrate onto which it is desired to deposit a material—e.g. for the purpose of coating the substrate.

And as it will be further mentioned, an application of this invention is the deposition of material onto a substrate for making successive layers in order to make a multilayer coating for a EUVL mask blank. Such application is however not a limitation of the scope of the invention.

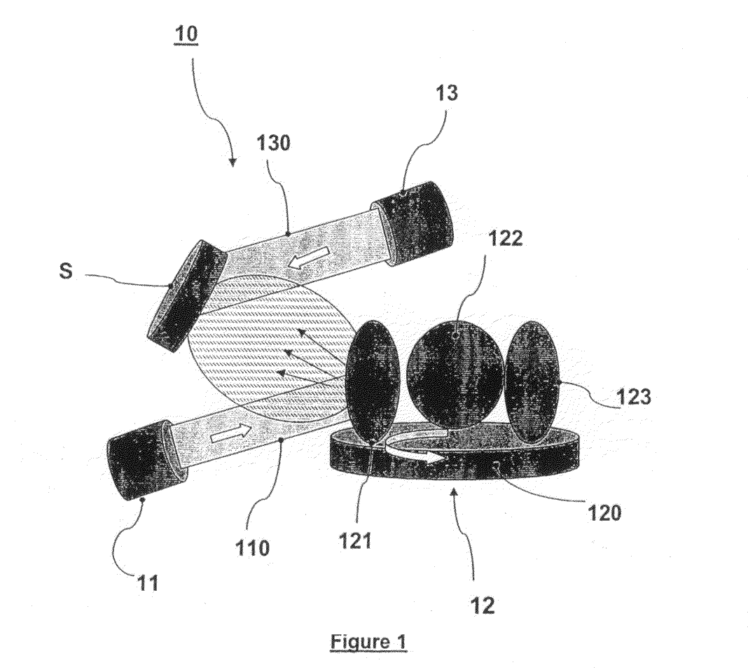

FIG. 1 shows a typical DIBS apparatus 10. This apparatus is comprised of a vacuum chamber (whose walls are not represented on the figure) with the following elements:
A first ion gun 11—referred to as a sputtering gun—for generating an ion flux 110 (e.g. ions such as Ar+, Kr+, Xe+, . . . ). This ion flux generated by the gun 11 shall be called sputtering ion beam. The gun 11 can be an ion source of the gridded RF or DC ion source type, or of a end-Hall effect ion source type, or of any other type of known ion source,
A target assembly 12 which comprises at least a target for receiving the flux 110 (in the example illustrated in FIG. 1, the target assembly 12 comprises three targets 121, 122, 123 which can be selectively exposed to flux 110 by means 120 such as a rotating tower). When the flux 110 strikes a target of the target assembly 12 it sputters material from such target, and said sputtered material is then deposited onto a substrate S—the substrate being thus coated by the material sputtered from the target,
A second ion gun 13—referred to as an assistance gun—for generating an ion flux 130 directed towards the substrate. This ion flux generated by the gun 13 shall be called assistance ion beam.

The gun 11 generates high energy ions (having an energy typically higher than 500 eV), for sputtering material from the target hit by the beam 110.

The assistance ion beam 130 can be used for different purposes. It can in particular allow the following applications:
Conditioning the surface of the substrate S by eliminating in particular the organic impurities before the coating of the substrate by the sputtered material,
Doping a thin film of material which has been deposited on the substrate, e.g. with an element such as oxygen,
Smoothing a thin film of material which has been deposited on the substrate (e.g. reducing the surface roughness of such material),
Etching portions of surface layers of a coating of the substrate—e.g. for rendering uniform the thickness of said layers.

The last application of the beam 130 which has been mentioned allows in particular to eliminate defects at the surface of layers stacked over the substrate, which correspond to local thickness variations resulting from the presence of a particulate contaminant within the thickness of the stack. This aspect shall be further described hereinafter in this text.

DIBS deposition methods have different applications—among which the multilayer coating of substrates—among others to manufacture lithography mask blanks.

For such application DIBS methods are generally well adapted since they allow to build onto a substrate films having only very few particulate contaminants.

Particulate contaminants (which shall in the rest of this text simply be referred to as “contaminants”) are herein defined as particles or aggregates of particles which are present into the deposition chamber and are not directly generated by the sputtering process (it is specified that the particles or aggregates defined as being “directly generated by the sputtering process” are those generated by the sputtering of the target(s), excluding the particles generated by the sputtering of impurities on the target(s)).

Such contaminants can be e.g. dust or aggregates of materials which have initially been sputtered and have been accumulated on the walls of the chamber before a flaking process occurs to detach them from said walls.

These contaminants can also be generated by the ion gun themselves—these guns being in this respect a source of pollution for the chamber.

For applications such as the manufacturing of a multilayer coating for a lithography mask, it is of particular importance to limit as much as possible such contaminants into the coating. This aspect shall be further described hereinafter.

The recent developments of lithography techniques have lead to the investigation of a technology which uses light in the extreme ultra violet (EUV) wavelength range.

This type of lithography is known as EUVL (acronym of Extreme Ultra Violet Lithography).

EUVL technology is being considered in particular for the manufacturing of future generation integrated circuits corresponding to nodes 32 nm and 22 nm, to allow the etching of circuit lines having extremely small dimensions.

Such lithography technology requires specific reflective masks.

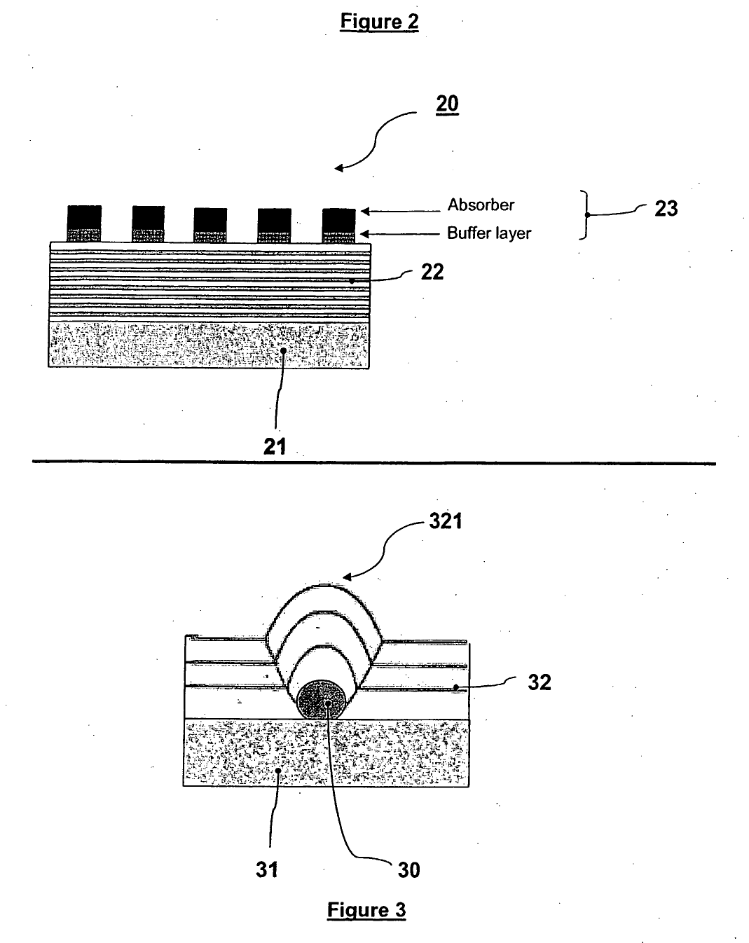

A reflective EUVL mask 20 is schematically illustrated in FIG. 2.

This mask comprises a substrate 21 having a low thermal expansion coefficient, covered by a multilayer coating 22.

The multilayer coating is typically composed of an alternation of Mo and Si layers.

The coating 22 is able to reflect EUV rays.

And this coating 22 is itself partially covered by a structure 23 which absorbs the EUV rays. This structure defines over the surface of the coating a pattern absorbing the EUV rays (the absorbing pattern is on the view of FIG. 2 illustrated by the discontinuity of structure 23).

The multilayer coating of such EUVL masks has to respect very strict specifications particularly in terms of defects.

In particular, for EUVL masks it is necessary to totally avoid parasitic deposition of contaminants whose dimensions are larger than a certain critical size, during the deposition of the layers which shall then form the multilayer coating 22.

The “parasitic deposition” is defined in this text as the deposition of contaminants as defined above.

The “critical size” considered as today for EUV lithography mask blanks is in the order of 35 to 50 nm (the critical size varies according to the node which is considered).

We shall refer in this text to:
“large” contaminants as those whose size (i.e. a typical dimension, such as a diameter) is larger than the critical size, for the node considered,
“small” contaminants as those whose size is smaller than the critical size, for the node considered.

This notion of critical size and its impact on the quality of a multilayer coating for an application such as the manufacturing of EUV lithography mask blanks shall be further explained in this text.

It has been stated that for applications such as the manufacturing of EUV lithography mask blanks, it is desired to eliminate parasitic deposition of large contaminants.

And for such applications, it is also desired to reduce as much as possible parasitic deposition of small contaminants.

Parasitic deposition in a multilayer coating such as those used for manufacturing EUV lithography mask blanks generate in particular two types of defects:
parasitic deposition of small contaminants generates perturbations within the thickness of the multilayer—in particular “nodules” which shall be further explained hereinafter—which degrade the reflective properties of the multilayer, in particular by creating phase perturbations of the reflected rays,
parasitic deposition of large contaminants within the thickness of the multilayer:
   also generates perturbations such as nodules,
   and further generates perturbations of the reflective properties of the multilayer, among others because these large contaminants absorb a portion of the incident EUV rays over a significant surface area, thus possibly creating amplitude perturbations of the reflected rays.

FIG. 3 illustrates an example of a nodule.

This figure schematically shows in a cross section view a multilayer coating 32 made over a substrate 31. It is specified that for the purpose of this illustration only three layers have been represented—the multilayer 32 can of course be comprised of a much larger number of layers.

A contaminant 30 is also shown on this figure.

The contaminant 30 is the result of an undesired parasitic deposition on the substrate 31 (or on one of the layers of the multilayer stack 32) during the making of the multilayer 32 by deposition of successive layers.

This figure shows that the contaminant 30 generates a perturbation of the shape of the successive layers which cover said contaminant.

And the lateral amplitude of such perturbations can grow with every successive layer.

This amplification generates a surface perturbation 321 on the multilayer coating.

And it is such structure of stacked layers, with a perturbation which grows along the layers, which forms a nodule.

The perturbation 321 will alter the reflective properties of the structure formed by the multilayer coating 32, and will generate phase perturbations of the reflected EUV rays.

Thus, contaminants which are defined in this text as <<small >> can generate phase perturbations of the reflected EUV rays.

And large contaminants furthermore generate amplitude perturbations of such reflected rays.

A known technique for limiting the growth of such nodules consists in etching, with the assistance ion gun of a DIBS apparatus, a portion of some layers of the multilayer 22 during the growth of said multilayer, in order to progressively planarize (i.e. make plane) the surface of these layers. Such technique is for example exposed by Mirkarimi et al. in “Developing a viable multilayer coating process for extreme ultraviolet lithography reticles”. Journal of Microlithography, Microfabrication and Microsystems (January 2004).

In such case, the etching of a given layer is performed either immediately after the deposition of said layer, and/or during the deposition of said layer.

Such treatment can limit the growth of nodules (i.e. limit the amplification of the perturbations in the successive layers of the coating), and bring the size of a surface perturbation (such as the perturbation 321) down to a size which is small enough to avoid any noticeable perturbation of the reflective properties of the multilayer.

But such treatment, as carried out under conditions such as known today, can itself generate additional parasitic depositions (of small and large contaminants) on the treated multilayer.

This corresponds to a pollution of the multilayer—and said pollution shall in turn generate additional defects.

The known DIBS methods are thus associated to the drawback of generating parasitic deposition, among others when carrying out the above-mentioned ion assistance technique for limiting the growth of nodules in a multilayer.

These known DIBS methods are thus not well adapted for applications such as the manufacturing of multilayer coatings for EUVL mask blanks.

Moreover, the source of a significant part of the contaminants observed on the substrates (or in the thickness of the multilayer coatings) is believed to be associated with the ion gun themselves.

Indeed, the ion beams of both the sputtering gun and the assistance gun of a DIBS apparatus can entrain and transport particles present on the path of said beams (such entrainment resulting from the kinetic energy transfer taking place during the collisions between the ions of the ion beam and the particles present on their path).

This results in the “pollution” of the beams themselves with contaminants which are “caught” by the flow of the beam and entrained by it.

We shall refer in this text to such contaminants caught in the flow of an ion beam as “transported” contaminants. This phenomenon of contaminant transportation by a beam is exposed e.g. by Walton et al. in “Understanding particle defect transport in an ultra clean sputter coating process”, SPIE Emerging Lithographic Technologies VII (2003).

Furthermore, in the case of the assistance ion beam of a DIBS apparatus, such transported contaminants are directly directed towards the substrate—which corresponds to the path of the assistance ion beam.

Transported contaminants can also be brought onto the substrate through the sputtering beam after an impact on the target hit by said beam (in this case the contaminants can be directed on the substrate directly from the target, or after bouncing on the walls or other parts of the chamber).

A known technique for limiting the pollution of a substrate by transported contaminants in a ion beam sputtering (IBS) deposition apparatus consists in using a specific ion gun whose beam is directed so as to form a protective zone in front of the substrate to be coated, and deflect the contaminants that could be transported by the sputtering beam.

This specific ion gun can be referred to as a “screen gun” and its beam can be referred to as a “screen beam”.

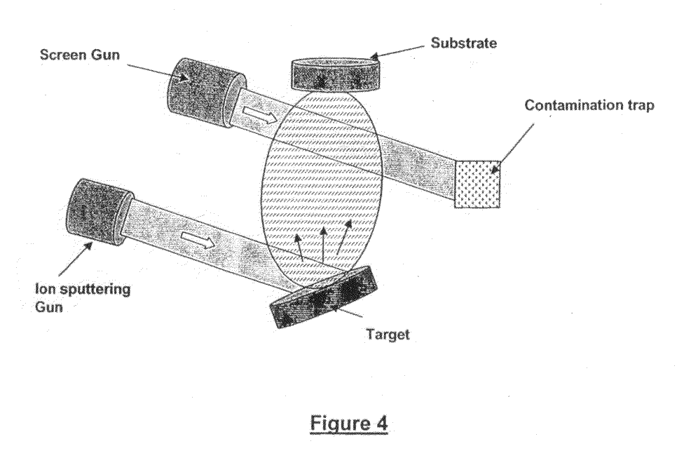

US 2004/0055871 discloses such a technique, with a screen gun (referenced 30 in this document) whose screen beam is directed towards a portion of space in front of the substrate to be protected from contaminants—said screen beam being not directed towards—the substrate. An apparatus with these features is schematically illustrated in FIG. 4 of the present application.

The contaminants caught by the screen beam are transported away to a contaminant trap, so that they will not re-circulate within the chamber.

Such an apparatus described in US 2004/0055871 is an IBS apparatus which does not comprise an assistance ion gun.

For the purpose of reducing the contaminants deposited onto a substrate in a DIBS apparatus, one could contemplate the possibility of integrating a screen gun such as the one disclosed in US 2004/0055871 in a DIBS apparatus which would already comprise a sputtering ion gun and an assistance ion gun.

But this would lead to an apparatus with three ion guns, which would significantly increase the cost of the apparatus as well as the complexity of said apparatus and of its operation.

Furthermore, the mere fact of adding a third ion gun within the chamber would increase the global amount of contaminants initially generated.

Thus, it appears that there is a need for reducing the contaminants deposited onto a substrate in a DIBS apparatus.

The goal of the invention is to meet this need.

For this purpose, the invention proposes a Dual Ion Beam Sputtering method for depositing onto a substrate material generated by the sputtering of a target by a sputtering ion beam, said method comprising the operation of an assistance ion beam directed onto said substrate in order to assist the deposition of material, said method being characterized in that during the operation of said assistance beam said sputtering beam is also operated in association with said assistance beam, and during said operation of the sputtering beam in association with the assistance beam the sputtering beam crosses a desired part of the assistance beam in order to transport contaminants associated to said desired part of the assistance beam away from said substrate.

Preferred, but non limiting aspects of this method are:
during the simultaneous operation of the sputtering beam and the assistance beam the sputtering beam is also used for sputtering a target,
during the simultaneous operation of the sputtering beam and the assistance beam the sputtering beam is only used in order to transport contaminants associated to said desired part of the assistance beam away from said substrate,
during the simultaneous operation of the sputtering beam and the assistance beam a moveable shield is applied in front of the target to prevent from sputtering,
said desired part of the assistance beam corresponds to the part of the assistance beam which is directed onto a desired area of the surface of the substrate,
said desired part of the assistance beam includes the whole section of the assistance beam,
said desired area of the substrate corresponds to the whole surface of the substrate,
said desired area of the substrate corresponds to a portion only of the surface of the substrate, for which it is specifically desired to establish a protection against the deposition of contaminants,
said target is located in a place opposite to the sputtering gun generating said sputtering beam with respect to the path of said assistance beam,
said sputtering beam strikes said target which is exposed to it with a striking angle which correspond to an optimal angle for sputtering,
said striking angle is 45°+/−20°,
said striking angle is defined so as to avoid that after striking the target the sputtering beam produces a reflected beam directed onto the substrate,
said assistance beam arrives onto the substrate with an angle in the order of 90° (close to normal incidence),
said assistance beam is operated only when the sputtering beam is itself operating,
said sputtering and assistance beams carry ions which are of the same sign,
at least one of said two beams is electrically neutralized,
both of said two beams are electrically neutralized,
the path of the sputtering beam is located as close as possible to the surface of the substrate,
the minimum distance between the path of the sputtering beam and the substrate is defined by the minimum distance avoiding any significant etching of the substrate by the sputtering beam, taking into account the divergence of said beam,
the distance between the substrate and the sputtering beam is between 2-5 cm,
in order to maximize the screening effect, the parameters of the sputtering and assistance beams are appropriately selected,
the current density and/or the energy of the sputtering beam and/or the mass of the ions constituting the sputtering beam is significantly greater than the respective corresponding parameters of the assistance beam,
the selection of the parameters of the sputtering beam (energy, current density, but also nature of the ions of the beam) shall be made as a function of the nature of the ions of the assistance beam, their energy and the associated current,
said selection of parameters also takes into account a desired sputtering rate,
said sputtering beam is a beam of Xe+ ions with an energy of 600 eV and said assistance beam is a beam of Ar+ ions having an energy of 250 eV,
the current density and the cross-section area of the two beams are equivalent, and the crossing section of the two beams is 20 cm*20 cm.

The invention furthermore proposes the application of a method according to one or several aspects mentioned above to:
the deposition of material in order to make a thin film for the production of advanced lithographic mask blanks. Such application can comprise the deposition of material onto a substrate for making successive layers in order to make a multilayer coating for a EUVL mask blank,
the deposition of material in order to make a giant magnetoresistive (GMR) multilayer.

For applications such as mentioned above the sputtering and assistance beams can be controlled so as to alternate:
deposition phases where only the sputtering beam is operated to deposit one or a few additional layers on the substrate, while the assistance gun emits no beam, at least some deposition phases being followed by
an etching phase where both sputtering and assistance beams are operated.

And the invention also proposes an apparatus for carrying on a method according to one or several aspects mentioned above and/or to an application as mentioned above, characterized in that said apparatus comprises an assistance gun for generating an assistance beam and a sputtering gun for generating a sputtering beam, said sputtering gun being fixed, and the target(s) is (are) located in a place opposite to said sputtering gun with respect to the path of said assistance beam.

Preferred, but non-limiting aspects of such apparatus are the following:
said assistance beam arrives onto the substrate with an angle in the order of 90° (close to normal incidence),
said sputtering beam strikes said target which is exposed to it with a striking angle which correspond to an optimal angle for sputtering,
said striking angle is 45°+/−20°,
said striking angle is defined so as to avoid that after striking the target the sputtering beam produces a reflected beam directed onto the substrate,
the path of the sputtering beam is located as close as possible to the surface of the substrate, at a minimum distance between the path of the sputtering beam and the substrate defined by the minimum distance avoiding any significant etching of the substrate by the sputtering beam, taking into account the divergence of said beam,
the distance between the substrate and the sputtering beam is between 2-5 cm,
said apparatus comprises control means connected to both sputtering and assistance guns in order to synchronize the operation of said assistance gun so that said assistance beam is operated only when the sputtering beam is itself operated,

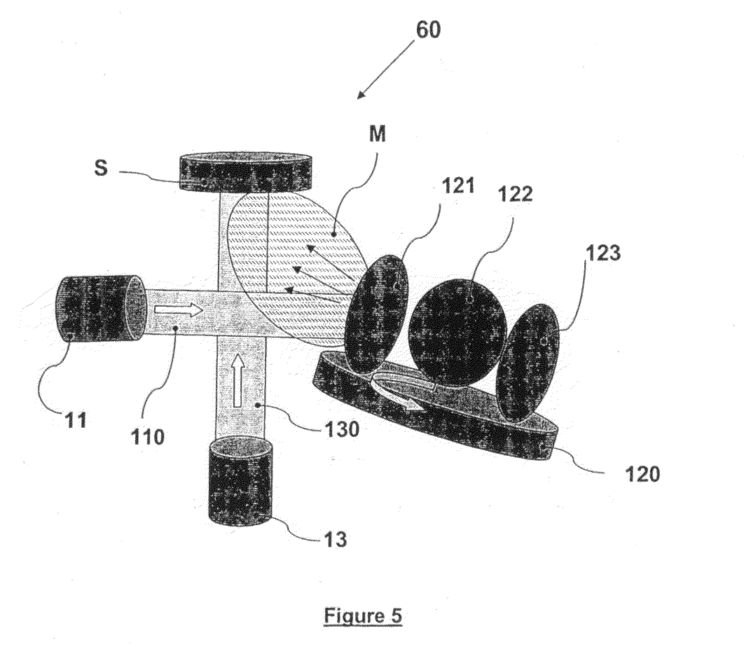

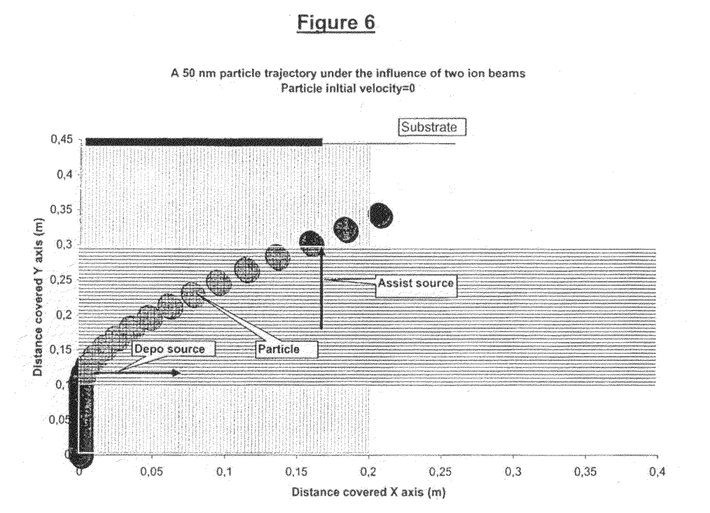

Other aspects, goals and advantages of the invention shall be further understood with the following description of the invention, made in reference to the accompanying drawings on which, in addition to FIGS. 1 to 4 which have already been commented above:
FIG. 5 is a schematic view of a particular embodiment of an apparatus according to the invention,
FIG. 6 is a graph generated by a numerical simulation and illustrating the effect of the invention on a contaminant.

FIG. 5 shows a schematic example of an apparatus 60 according to the invention.

This figure comprises (in a vacuum chamber whose walls are not represented on the figure) elements which are similar to elements commented earlier in this text in reference to FIG. 1. Such elements are here again associated to the same numeral references.

These elements are:
A sputtering ion gun 11 for generating a sputtering ion beam or flux 110,
A target assembly 12 with three targets 121, 122, 123, selectively exposed to the sputtering beam 110 by the rotation of means 120 such as a rotating tower,
An assistance ion gun 13 for generating an assistance ion beam or flux 130 directed towards a substrate S.

All comments made hereabove in reference to FIG. 1 are applicable to similar elements of this FIG. 5.

This apparatus 60 is thus generally of the DIBS type—and it is designed for carrying on a deposition by a DIBS method. For depositing onto the substrate S material generated by the sputtering of a target 121, 122, 123 by the sputtering ion beam 110, said method comprises the operation of the assistance ion beam 130 directed onto the substrate in order to assist the deposition of material.

In the case of the invention, the DIBS apparatus is arranged and operated so that:
during the operation of the assistance beam 130 the sputtering beam 110 is also operated in association with said assistance beam,
and during said operation of the sputtering beam in association with the assistance beam the sputtering beam crosses a desired part of the assistance beam in order to transport contaminants associated to said desired part of the assistance beam away from said substrate.

It is specified that a “part” of the assistance beam refers to a part of the volume occupied by this beam.

FIG. 5 therefore shows a sputtering beam 110 which crosses the path of the assistance beam 130.

More precisely, said “desired part” of the assistance beam corresponds to the part of the assistance beam 130 which is directed onto a desired area of the surface of the substrate S.

And this “desired part” of the assistance beam can include the whole section of the assistance beam (in such case all rays of the beam 130 are crossed by the beam 110).

The desired area of the substrate can correspond to the whole surface of the substrate (it is specified that in this text the “surface of the substrate” is understood as the actual surface of the substrate, or the surface of the last layer deposited onto the substrate).

Alternatively, the desired area of the substrate can correspond to a portion only of the surface of the substrate, for which it is specifically desired to establish a protection against the deposition of contaminants.

The sputtering beam 110 indeed plays the role of a “shield” (or screen) placed between the assistance gun 13 and the substrate.

When the assistance beam is operating, the sputtering beam thus fulfils a function analogous to the function of the screen beam of the screen gun 30 commented hereabove in reference to FIG. 4.

In other words, the (part of the) assistance beam 130 which is crossed by the sputtering beam 110 is treated by said sputtering beam (which in the case of the invention is also a screen beam), and the contaminants initially present in the assistance beam and caught by the crossing screen beam 110 are transported away from the substrate S.

In this manner, it is possible to operate a DIBS apparatus and method with a protection against the deposition of contaminants transported by the assistance beam—but without requiring a third ion gun to be incorporated into the apparatus.

In order to enable the sputtering beam to both sputter the target and also cross the assistance beam the target(s) are located in a place opposite to the sputtering gun with respect to the path of the assistance beam. Such arrangement is illustrated in FIG. 5.

The arrangement in FIG. 5 illustrates a particular embodiment of the invention.

In this embodiment:
the guns 11 and 13 and their orientations are fixed, and the target(s) are arranged in a place opposite to the sputtering gun with respect to the path of the assistance beam,
the sputtering beam 110 strikes the target which is exposed to it with a striking angle which correspond to an optimal angle for sputtering—e.g. 45°+/−20° from the normal direction to the plane of the target,
   another consideration which can dictate the definition of the striking angle of the sputtering beam onto the target(s) is that it should preferably be avoided that after striking the target the sputtering beam produces a reflected beam directed onto the substrate. If this was the case indeed, the reflected beam would transport contaminants carried away by the sputtering beam onto the substrate,
the assistance beam 130 arrives onto the substrate S with an angle in the order of 90° (close to normal incidence). Here again this value is not limitative. It is however well suited for the creation of a structure such as a EUVL mask blank onto the substrate, by deposition of a Mo/Si multilayer,
the directions of the two beams 110 and 130 form an angle which is in the order of 90°. This value of the angle between the beams 110 and 130 is not limitative and is specific of the embodiment illustrated in FIG. 5. The respective directions of the two beams can define an angle which is optimized to maximize the screening effect of the sputtering beam while enabling good deposition conditions such as those disclosed hereabove (referring to the orientation of the sputtering beam towards the target and/or the assistance beam towards the substrate).

The assistance beam is preferably operated only when the sputtering/screen beam 110 is itself operated, which requires a synchronization of the operation of the two beams—and for the purpose of such synchronized operation adequate control means, connected to both guns 11 and 13, are provided.

The two beams 110, 130 typically carry ions which are of the same sign (e.g. Ar+, Kr+, Xe+, . . . ).

In order to avoid repulsion between the ions of the two beams—which cross—these beams are preferably electrically neutralized. Alternatively, only one of these two beams is neutralized.

A respective neutraliser can thus be associated to each of the beams 110, 130 (or only a neutralizer can be associated to one of the beams). Such neutraliser(s) can e.g. emit electrons in the proximity of the ion beam to neutralize the space charge associated with such beam.

In order to maximize the screening effect of the sputtering beam 110 the path of the beam 110 should be located as close as possible to the surface of the substrate.

In this respect, the minimum distance between the path of the beam 110 and the substrate is defined by the minimum distance avoiding any significant etching (or sputtering) of the substrate by the beam 110, taking into account the divergence of said beam 110.

The more divergent the beam 110 the bigger this distance should be in order to avoid etching (or sputtering) by the beam 110. Typically the distance between the substrate and the beam 110 could be 2-5 cm.

Furthermore, still in order to maximize the screening effect, the parameters of the beams 110 and 130 should be appropriately selected.

More precisely, the current density and/or the energy of the sputtering beam 110 and/or the mass of the ions constituting the sputtering beam 110 should be significantly greater than the respective corresponding parameters of the assistance beam 130. In this way the influence of the beam 110 shall be greater and the contaminants from the beam 130 shall efficiently be transported away from the substrate after crossing the beam 110.

The selection of the parameters of the beam 110 (energy, current density, but also the nature of the ions of the beam 110) shall be made as a function of the nature of the ions of the beam 130 (which defines their mass), their energy and the associated current.

This selection shall also take into account a desired sputtering rate, since the beam 110 is also used for sputtering the target(s). An optimization shall thus be made taking into account both objectives of maximization of the screening effect and adaptation of a desired sputtering rate.

As an example, the applicant has determined that a sputtering beam of Xe+ ions with an energy of 600 eV could efficiently screen an assistance beam of Ar+ ions having an energy of 250 eV. In this example, the current density and the cross-section area of the two beams were equivalent, and the crossing section of the two beams was 20 cm*20 cm.

FIG. 6 shows the results of a numerical simulation illustrating such an example, with the path of a contaminant (represented as a grey disk) represented as a function of time. The contaminant of this example has a diameter of 50 nm and is a particle of molybdenum.

The following table provides values used for the parameters of this simulation.

| | | | |
|---|---|---|---|
| Extraction Voltage | 600 | Extraction Voltage | 250 |
| (Volts) | | (Volts) | |
| Deposition source | | Assist source | |
| Deposition source | Xe | Assist source gas | Ar |
| gas | | | |
| Particle radius (nm) | 25 | Particle radius (nm) | 25 |
| Particle type | Mo | Particle type | Mo |
| Deposition Beam | 0.15 | Assist Beam | 0.15 |
| current (A) | | current (A) | |
| Sputtering Beam | 10 | Assist Beam radius | 10 |
| radius (cm) | | (cm) | |

The vertical axis of FIG. 6 corresponds to the direction of the assistance beam 130, and the horizontal axis to the direction of the sputtering/screen beam 110. The substrate is represented (lying along the horizontal direction of the figure) in the upper part of the figure. In this example, the directions of the assistance beam and the sputtering beam form an angle of 90°.

The graph of FIG. 6 shows a transportation of the contaminant, away from the substrate.

Such example corresponds to values for the beams 110 and 130 which are well-suited for applications such as deposition of material onto a substrate for making successive layers in order to make a multilayer coating for a EUVL mask blank. This application is however not limitative. Indeed the DIBS method described in the invention can be used for other applications requiring low contamination deposition such as for the production of advanced lithographic mask blanks, for the production of giant magnetoresistive (GMR) multilayers or for the production of thin films in IC manufacturing.

For applications where the assistance beam 130 is used to etch portions of surface layers of a coating of the substrate—e.g. for rendering uniform the thickness of said layers by eliminating the surface perturbations of nodules in the layers already deposited—this beam 130 is operated only after a deposition step has been carried on.

In such applications, it is possible to control the beams 110 and 130 so as to alternate:
deposition phases where only the sputtering beam is operated to deposit one or a few additional layers on the substrate, while the assistance gun emits no beam, at least some deposition phases being followed by
an etching phase where both beams 110 and 130 are operated
   In such etching phase, in a preferred embodiment the sputtering beam fulfils both functions of screening of the beam 130 and sputtering of a target (which leads to material deposition on the substrate).
   Alternatively the sputtering beam 110 can be used during this phase only to screen the assistance beam 130. In this case a movable shield can be applied in front of the target to prevent from sputtering the target. In this particular embodiment, the shield constitution should enable to prevent from parasitic sputtering and the sputtering beam energy can also be reduced to prevent from parasitic sputtering of the shield.

Such application with alternating phases can be used for making EUVL mask blanks. And it is to be noted that in such case (or more generally for etching nodules of a multilayer) orienting the assistance beam in a direction which corresponds, or is as close as possible, to the normal of the plane of the substrate is preferred since such orientation of the beam 130 allows a particularly efficient etching of the nodules.

1-38. (canceled)

39. Dual Ion Beam Sputtering method for depositing onto a substrate material generated by the sputtering of a target by a sputtering ion beam, said method comprising the operation of an assistance ion beam directed onto said substrate in order to assist the deposition of material, said method being wherein during the operation of said assistance beam said sputtering beam is also operated in association with said assistance beam, and during said operation of the sputtering beam in association with the assistance beam the sputtering beam crosses a desired part of the assistance beam in order to transport contaminants associated to said desired part of the assistance beam away from said substrate.

40. The method of claim 39 wherein during the simultaneous operation of the sputtering beam and the assistance beam the sputtering beam is also used for sputtering a target.

41. The method of claim 39 wherein during the simultaneous operation of the sputtering beam and the assistance beam the sputtering beam is only used in order to transport contaminants associated to said desired part of the assistance beam away from said substrate.

42. The method of claim 40 wherein during the simultaneous operation of the sputtering beam and the assistance beam a moveable shield is applied in front of the target to prevent from sputtering

43. The method of claim 39 wherein said desired part of the assistance beam corresponds to the part of the assistance beam which is directed onto a desired area of the surface of the substrate.

44. The method of claim 43 wherein said desired part of the assistance beam includes the whole section of the assistance beam.

45. The method of claim 43 wherein said desired area of the substrate corresponds to the whole surface of the substrate.

46. The method of claim 43 wherein said desired area of the substrate corresponds to a portion only of the surface of the substrate, for which it is specifically desired to establish a protection against the deposition of contaminants.

47. The method of claim 39 wherein said target is located in a place opposite to the sputtering gun generating said sputtering beam with respect to the path of said assistance beam.

48. The method of claim 39 wherein said sputtering beam strikes said target which is exposed to it with a striking angle which correspond to an optimal angle for sputtering.

49. The method of claim 48 wherein said striking angle is 45°+/−20°.

50. The method of claim 48 wherein said striking angle is defined so as to avoid that after striking the target the sputtering beam produces a reflected beam directed onto the substrate.

51. The method of claim 39 wherein said assistance beam arrives onto the substrate with an angle in the order of 90° (close to normal incidence).

52. The method of claim 39 wherein said assistance beam is operated only when the sputtering beam is itself operating.

53. The method of claim 39 wherein said sputtering and assistance beams carry ions which are of the same sign.

54. The method of claim 53 wherein at least one of said two beams is electrically neutralized.

55. The method of claim 54 wherein both of said two beams are electrically neutralized.

56. The method of claim 39 wherein the path of the sputtering beam is located as close as possible to the surface of the substrate.

57. The method of claim 56 wherein the minimum distance between the path of the sputtering beam and the substrate is defined by the minimum distance avoiding any significant etching of the substrate by the sputtering beam, taking into account the divergence of said beam.

58. The method of claim 57 wherein the distance between the substrate and the sputtering beam is between 2-5 cm.

59. The method of claim 39 wherein in order to maximize the screening effect, the parameters of the sputtering and assistance beams are appropriately selected.

60. The method of claim 59 wherein the current density and/or the energy of the sputtering beam and/or the mass of the ions constituting the sputtering beam is significantly greater than the respective corresponding parameters of the assistance beam.

61. The method of claim 59 wherein the selection of the parameters of the sputtering beam (energy, current density, but also nature of the ions of the beam) shall be made as a function of the nature of the ions of the assistance beam, their energy and the associated current.

62. The method of claim 61 wherein said selection of parameters also takes into account a desired sputtering rate.

63. The method of claim 59 wherein said sputtering beam is a beam of Xe+ ions with an energy of 600 eV and said assistance beam is a beam of Ar+ ions having an energy of 250 eV.

64. The method of claim 63 wherein the current density and the cross-section area of the two beams are equivalent, and the crossing section of the two beams is 20 cm*20 cm.

65. Application of the method of claim 39 to the deposition of material in order to make a thin film for the production of advanced lithographic mask blanks.

66. The application of claim 65 wherein it comprises the deposition of material onto a substrate for making successive layers in order to make a multilayer coating for a EUVL mask blank.

67. Application of the method of claim 39 to the deposition of material in order to make a giant magnetoresistive (GMR) multilayer.

68. Application of the method of claim 39 wherein the sputtering and assistance beams are controlled so as to alternate:
deposition phases where only the sputtering beam is operated to deposit one or a few additional layers on the substrate, while the assistance gun emits no beam, at least some deposition phases being followed by
an etching phase where both sputtering and assistance beams are operated.

69. Apparatus for carrying on the method of claim 39 wherein said apparatus comprises an assistance gun for generating an assistance beam and a sputtering gun for generating a sputtering beam, said sputtering gun being fixed, and the target(s) is (are) located in a place opposite to said sputtering gun with respect to the path of said assistance beam.

70. The apparatus of claim 69 wherein said assistance beam arrives onto the substrate with an angle in the order of 90° (close to normal incidence).

71. The apparatus of claim 69 wherein said sputtering beam strikes said target which is exposed to it with a striking angle which correspond to an optimal angle for sputtering.

72. The apparatus of claim 71 wherein said striking angle is 45°+/−20°.

73. The apparatus of claim 71 wherein said striking angle is defined so as to avoid that after striking the target the sputtering beam produces a reflected beam directed onto the substrate.

74. The apparatus of claim 69 wherein the path of the sputtering beam is located as close as possible to the surface of the substrate, at a minimum distance between the path of the sputtering beam and the substrate defined by the minimum distance avoiding any significant etching of the substrate by the sputtering beam, taking into account the divergence of said beam.

75. The apparatus of claim 74 wherein the distance between the substrate and the sputtering beam is between 2-5 cm.

76. The apparatus of claim 69 wherein said apparatus comprises control means connected to both sputtering and assistance guns in order to synchronize the operation of said assistance gun so that said assistance beam is operated only when the sputtering beam is itself operated.
